(19) United States
(12) Patent Application Publication
(10) Pub. No.: US 2007/0148938 A1
(43) Pub. Date: Jun. 28, 2007

(54) Semiconductor device and method for fabricating the same

(75) Inventors: Sang-Yeop Han, Kyoungki-do (KR); Seung-A Shin, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor, Inc.

(21) Appl. No.: 11/479,257

(22) Filed: Jun. 29, 2006

(30) Foreign Application Priority Data
Dec. 23, 2005 (KR) 2005-0128685

(51) Int. Cl. H01L 21/3205; H01L 21/8238; H01L 21/76

(52) U.S. Cl. 438/587; 438/207; 438/424

(57) ABSTRACT

A method for fabricating a semiconductor device is provided. The method includes: forming an isolation layer over a substrate to define a field region and an active region; forming a step coverage layer over the isolation layer; and forming a plurality of gate lines traversing the field region and the active region over the substrate.

### RELATED APPLICATION

The present application contains subject matter related to the Korean patent application No. KR 2005-0128685, filed in the Korean Patent Office on Dec. 23, 2005, the entire contents of which being incorporated herein by reference.

### BACKGROUND

The present invention relates to a semiconductor device; and more particularly, to a semiconductor device and a method for fabricating the semiconductor device including an isolation layer.

As well known, a local oxidation of silicon (LOCOS) process which is a typical isolation process cannot be free from the Bird's beak phenomenon. It becomes hard to apply the LOCOS process to highly integrated semiconductor devices due to a decreased active region by the Bird's beak phenomenon.

A shallow trench isolation (STI) process introduced to improve the LOCOS process can settle unstable factors of the LOCOS process including degradation of a field oxide layer due to a decreased design rule of the semiconductor devices. The STI process also provides an outstanding effect in improving a defect of the Bird's beak phenomenon generated during the LOCOS process. Furthermore, the STI process is considered as an isolation process favorable for securing an active region, and a technology even applied to a fabrication process of ultra-highly integrated semiconductor devices with a size of Giga dynamic random access memory (DRAM) in the future.

As for the typical STI process, a silicon substrate is etched with a thickness ranging from about 0.2 μm to about 0.4 μm to form a trench. Afterwards, a gap-filling oxide layer is formed over the trench, and a chemical mechanical polishing (CMP) process is performed to insulate a space between active regions.

FIGS. 1A and 1B are cross-sectional views illustrating a typical method for fabricating a semiconductor device.

As shown in FIG. 1A, masks (not shown) are formed over predetermined portions of a substrate 11, and the substrate 11 is etched using the masks with a predetermined thickness ranging from about 0.2 μm to about 0.4 μm to form a plurality of trenches 12. Portions of the substrate 11 interposed between the trenches 12 are defined as active regions 13, and a gap-filling oxide layer 14 is formed over the entire surface of the substrate 11 including the trenches 12 to isolate devices.

As shown in FIG. 1B, a chemical mechanical polishing (CMP) process is performed to fill the gap-filling oxide layer 14 into the trenches 12. As a result, an isolation layer 14A is formed.

FIG. 2 is a top view of a semiconductor device fabricated by the typical method. The same reference numerals used in FIGS. 1A and 1B denotes the same constitution elements in FIG. 2.

As shown in FIG. 2, an isolation layer 14A is formed in a substrate 11 to define a plurality of active regions. A plurality of gate lines G are formed over the substrate 11.

Afterwards, a wet cleaning process is performed. During the wet cleaning process, lateral interfacial portions of the isolation layers 14A are often etched in a region B where the active regions 13 are disposed closed to each other (hereinafter, referred to as a narrow region B). However, in a region C where the active regions 13 are disposed away from each other (hereinafter, referred to as a wide region C), the interfacial portions of the isolation layers 14A with respect to the active regions 13 are minimally etched and thus, the isolation layers 14A are not damaged.

FIG. 3 is a cross-sectional view illustrating limitations associated with the typical method. Particularly, FIG. 3 illustrates the semiconductor device taken along a line A-A′, in FIG. 2 and the same reference numerals used in FIG. 2 are used to denote the same constitution elements in FIG. 3.

As shown in FIG. 3, the gate lines G are formed over the isolation layer 44A. During the aforementioned cleaning process performed after the formation of the gate lines G, in the narrow region B between the active regions 13, a predetermined thickness D of the isolation layer 14A is damaged; however, in the large area C, the isolation layer 14A is not damaged.

As described above, while the cleaning process is performed, the isolation layer is likely to be damaged in the horizontal direction to the gate lines in the narrow region B between the active regions.

More particularly to the result, since the etching occurs more rapidly in the interfaces between the active regions and the isolation layer than in other regions, the interfaces of the isolation layer are often severely damaged. In addition to the interfaces of the isolation layer with respect to the active regions, the interfaces of the isolation layer with respect to the gate lines are also damaged in the horizontal direction. Hence, the isolation layer is often damaged more severely in the narrow region B than in the wide region C.

While a subsequent process of forming transistors is performed after the STI process, the gap-filling oxide layer between the active regions may have a different height depending on the location of the trenches formed through the STI process. Thus, a defect may be generated in the semiconductor device.

Furthermore, an inter-layer insulation layer is formed between the gate lines to insulate the gate lines from each other. In FIG. 3, as reference denotation D indicates, the isolation layer formed in the narrow region tend to have a high aspect ratio due to the above described height difference in the isolation layer. Hence, the inter-layer insulation layer may not completely fill the space between the gate lines. Accordingly, a void is more likely to be formed in the unfilled spaces between the gate lines and a defect may be generated during a subsequent process.

### SUMMARY OF THE INVENTION

It is, therefore, an object of the present invention to provide a method for fabricating a semiconductor device capable of reducing a height difference in an isolation layer regionally generated depending on the location of the isolation layer between neighboring active regions.

In accordance with one aspect of the present invention, there is provided a method for fabricating a semiconductor device, including: forming an isolation layer over a substrate to define a field region and an active region; forming a step coverage layer over the isolation layer; and forming a plurality of gate lines traversing the field region and the active region over the substrate.

In accordance with another aspect of the present invention, there is provided a semiconductor device, including: a substrate defined with field regions and active regions; a step coverage layer formed over the isolation layer; and a plurality of gate lines traversing the field regions and the active regions over the step coverage layer.

In accordance with further aspect of the present invention, there is provided an isolation layer of a semiconductor device, including: an isolation layer formed over a substrate; a step coverage layer formed of a nitride-based material over the isolation layer; and a plurality of gate lines over the step coverage layer.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A and 1B are cross-sectional views illustrating a typical method for fabricating a semiconductor device;

FIG. 2 is a top view of a semiconductor device fabricated by the typical method;

FIG. 3 is a cross-sectional view illustrating limitations associated with the typical method for fabricating a semiconductor device;

FIGS. 4A to 4C are cross-sectional views illustrating a method for fabricating a semiconductor device in accordance with a specific embodiment of the present invention;

FIG. 5 is a top view illustrating a method for fabricating a semiconductor device in accordance with a specific embodiment of the present invention; and

FIG. 6 is a cross-sectional view illustrating the resulting structure illustrated FIG. 5 cut along a line I-I′.

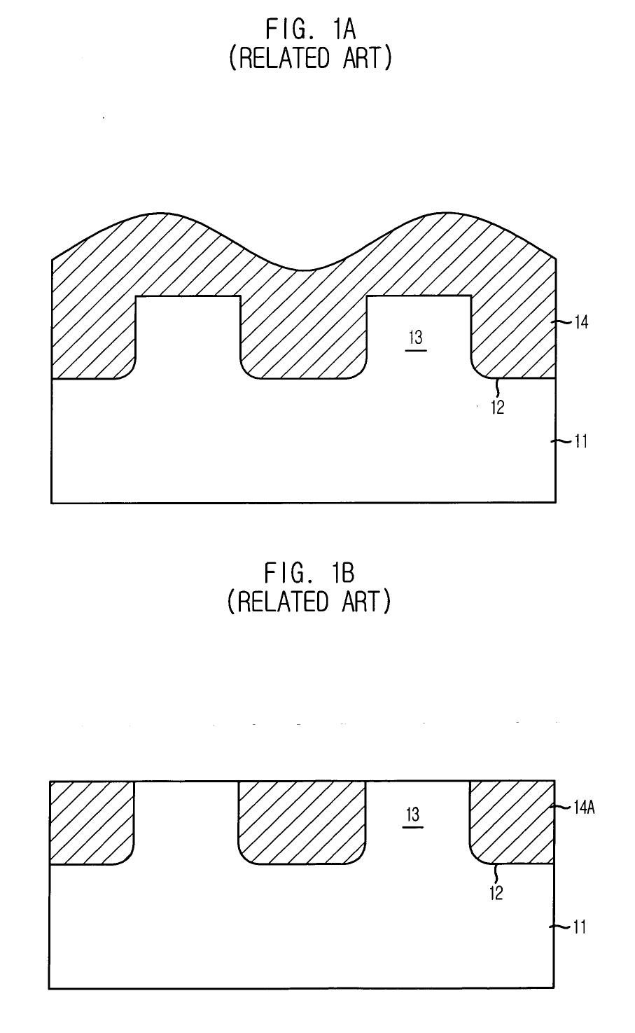

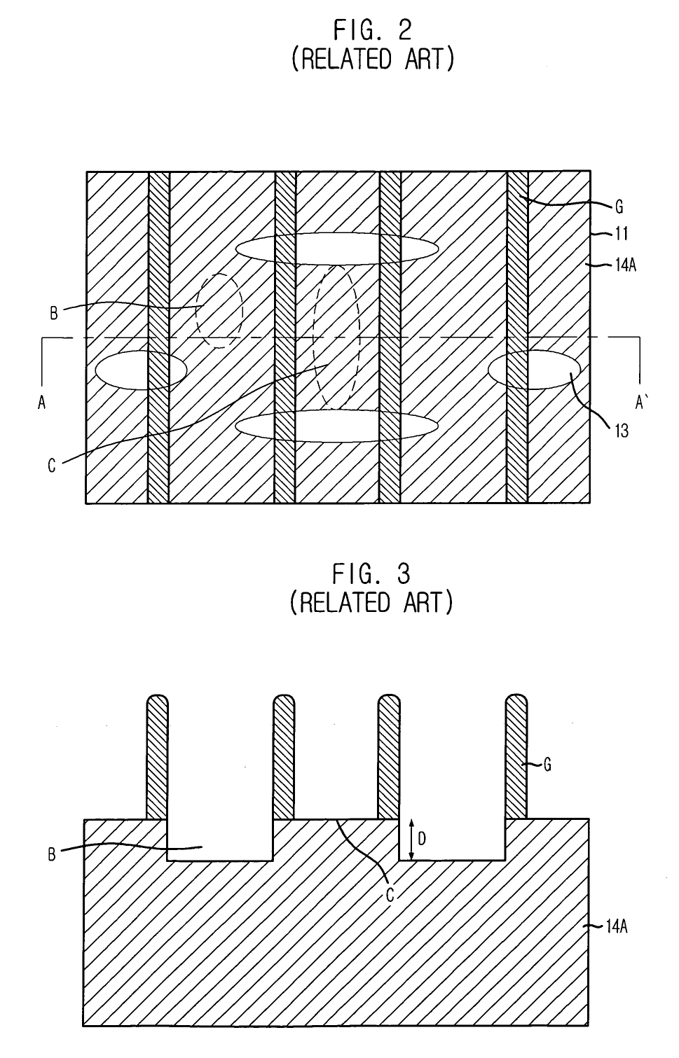

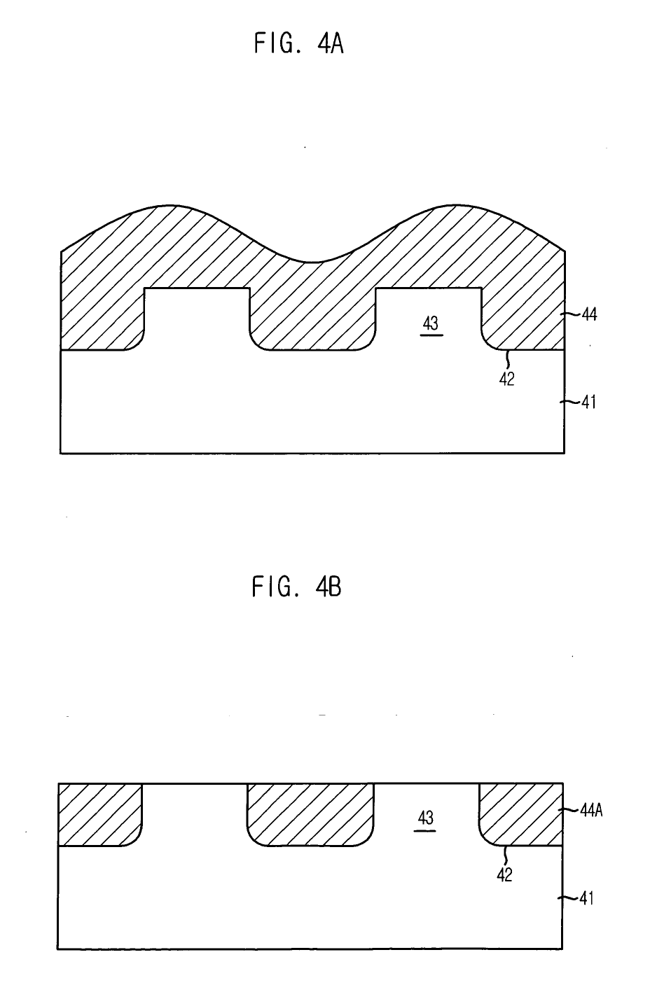

### DETAILED DESCRIPTION OF THE INVENTION

Hereinafter, detailed descriptions on certain embodiments of the present invention will be provided with reference to the accompanying drawings.

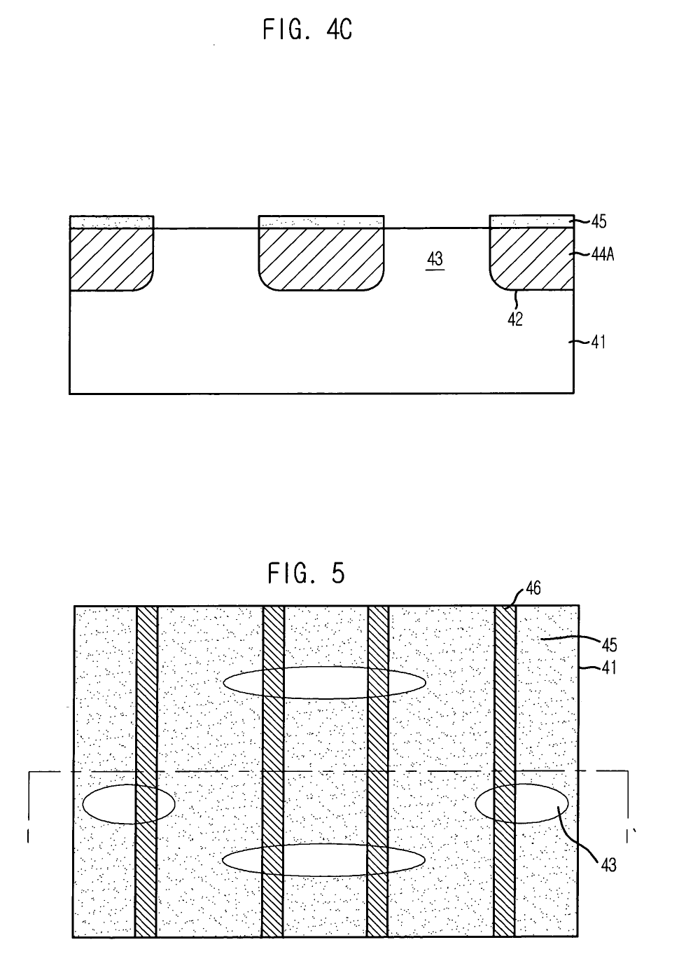

FIGS. 4A to 4C are cross-sectional views illustrating a method for fabricating a semiconductor device in accordance with a specific embodiment of the present invention.

As shown in FIG. 4A, a plurality of trench masks (not shown), each including a pad oxide layer and a pad nitride layer that are stacked in a sequential order are formed over predetermined portions of a substrate 41. The substrate 41 is etched with a thickness ranging from about 0.2 μm to about 0.4 μm using the trench masks to form a plurality of trenches 42. Except for the regions where the trenches 42 are formed, the remaining regions of the substrate 41 are defined as active regions 43.

A gap-filling oxide layer 44 is formed to fill the trenches 42 over the substrate 41 including the trenches 42. The gap-filling oxide layer 44 is formed of a high density plasma (HDP) layer in this specific embodiment of the present invention. However, the gap-filling oxide layer 44 can also include an oxide-based layer from the group consisting of a spin-on-glass (SOG) layer, an undoped silicate glass (USG) layer, a tetraethylorthosilicate (TEOS) layer, and a combination thereof.

As shown in FIG. 4B, a planarization process is performed to planarize the gap-filling oxide layer 44 with a target to expose the pad nitride layer of the trench masks. As a result, an isolation layer 44A is formed. The planarization process uses a chemical mechanical polishing (CMP) process.

As shown in FIG. 4C, a step coverage layer 45 is formed over the entire surface of the isolation layer 44A except for the active regions 43. The step coverage layer 45 serves a role in reducing a height difference in the isolation layer 44A.

The step coverage layer 45 is formed to a thickness ranging from about 1 nm to about 10 nm, and formed over a nitride-based layer.

Hereinafter, a method for forming the step coverage layer 45 will be explained.

The isolation layer 44A between the active regions 43 is subjected to a thermal treatment in one of a nitrogen (N₂) atmosphere and an ammonium (NH₃) atmosphere. As a result, the surface of the isolation layer 44A is selectively nitrified to form the step coverage layer 45.

In another method, the isolation device 44A between the active regions 43 is subjected to a thermal treatment in an atmosphere including N₂-based gas to selectively nitrify the isolation layer 44A, or the isolation layer 44A between the active regions 43 is selectively nitrified in an atmosphere including a plasma of N₂-based gas.

Furthermore, a silicon nitride (Si₃N₄) layer is formed over the active regions 43, and a silicon oxynitride (SiON) layer is formed over the isolation layer 44A. Afterwards, only the Si₃N₄ layer formed over the active regions 43 is selectively removed.

Forming the nitride-based step coverage layer 45 over the isolation layer 44A can reduce etch damage to the interfaces between the active regions 43 and the isolation layer 44A in narrow regions where the active regions 43 are disposed close to each other during a cleaning process performed after forming of typical gate lines.

FIG. 5 is a top view illustrating a method for fabricating an isolation layer of a semiconductor device in accordance with a specific embodiment of the present invention. The same reference numerals used in FIGS. 4A to 4C denote the same constitution elements in FIG. 5.

As shown in FIG. 5, an isolation layer (not shown) is formed in a substrate 41, thereby defining field regions and active regions 43. The step coverage layer 45 is formed only over the isolation layer (not shown).

A plurality of gate lines 46 are formed over the substrate 41.

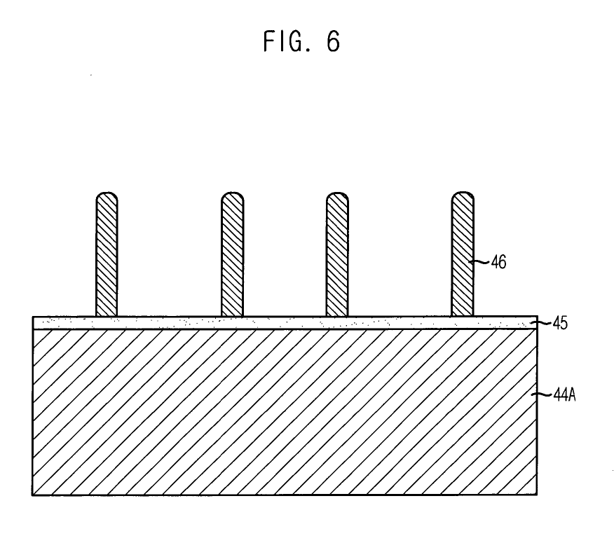

FIG. 6 is a cross-sectional view illustrating the semiconductor device taken along a line I-I′ in FIG. 5. The same reference numerals used in FIG. 5 denote the same constitution elements in FIG. 6.

As shown in FIG. 6, since the step coverage layer 45 is formed over the isolation layer 44A, it is possible to reduce an etch damage to the isolation layer 44A during a cleaning process performed after the forming of the gate lines 46.

As described above, to prevent a defect of a semiconductor device generated by a height difference locally formed in regions where an isolation layer is formed, a nitride-based step coverage layer is formed over the isolation layer. Thus, an etch damage of the isolation layer generated due to a wet chemical used during a post-cleaning process can be prevented.

In accordance with the specific embodiment of the present invention, a silicon nitride layer is formed with a thickness of about 10 nm over an isolation layer to reduce a height difference of the isolation layer in advance.

Also, when forming gate lines and an inter-layer insulation layer insulating the gate lines from each other, a void cannot be formed in a region where a relatively high aspect ratio is formed by reducing the height difference in the isolation layers.

Furthermore, in accordance with the specific embodiment of the present invention, yield of products can be increased.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor device, comprising:
forming an isolation layer over a substrate to define a field region and an active region;
forming a step coverage layer over the isolation layer; and
forming a plurality of gate lines traversing the field region and the active region over the substrate.

2. The method of claim 1, wherein the forming of the step coverage layer over the isolation layer includes performing a thermal treatment in an atmosphere including nitrogen (N₂)-based gas to selectively nitrify the isolation layer.

3. The method of claim 2, wherein the thermal treatment is performed in the atmosphere of the N₂-based gas including one of nitrogen (N₂) and ammonia (NH₃).

4. The method of claim 1, wherein the forming of the step coverage layer over the isolation layer comprises:
performing a thermal treatment in an atmosphere of a plasma including N₂-based gas; and
selectively nitrifying the isolation layer.

5. The method of claim 1, wherein the forming of the step coverage layer over the isolation layer comprises:
forming a photoresist layer over the isolation layer; and
performing one of a thermal treatment and a plasma treatment in an atmosphere of N₂-based gas to selectively nitrify the isolation layer.

6. The method of claim 1, wherein the forming of the step coverage layer over the isolation layer includes:
forming a silicon nitride layer over the active regions except for the isolation layer;
forming a silicon oxynitride layer over the isolation layer; and
selectively removing the silicon nitride layer.

7. The method of claim 1, wherein the step coverage layer is formed to a thickness ranging from about 1 nm to about 10 nm.

8. The method of claim 1, further comprising performing a cleaning process after forming the gate lines.

9. The method of claim 8, wherein the step coverage layer serves as an etch barrier during the cleaning process to reduce damage to the isolation layer.

10. A semiconductor device, comprising:
a substrate defined with field regions and active regions;
a step coverage layer formed over the isolation layer; and
a plurality of gate lines traversing the field regions and the active regions over the step coverage layer.

11. The semiconductor device of claim 10, wherein the step coverage layer is formed of a nitride-based layer.

12. The semiconductor device of claim 11, wherein the step coverage layer is formed to a thickness ranging from about 1 nm to about 10 nm.

13. An isolation layer of a semiconductor device, comprising:
an isolation layer formed over a substrate;
a step coverage layer formed of a nitride-based material over the isolation layer; and
a plurality of gate lines over the step coverage layer.

14. The isolation layer of claim 13, wherein the step coverage layer is formed to a thickness ranging from about 1 nm to about 10 nm.
